(19) United States
(12) Patent Application Publication
(10) Pub. No.: US 2013/0070424 A1
(43) Pub. Date: Mar. 21, 2013

(54) Molded can package

(71) Applicant: Chung Hsing TZU, Taipei County (TW)

(72) Inventor: Chung Hsing TZU, Taipei County (TW)

(73) Assignee: Great Team Backend Foundry, Inc., British Virgin Islands (GB)

(21) Appl. No.: 13/539,453

(22) Filed: Jul. 1, 2012

Related U.S. Application Data
(60) Provisional application No. 61/503,619, filed on Jul. 1, 2011.

(51) Int. Cl. H05K 5/00

(52) U.S. Cl. CPC H05K 5/0091
USPC 361/728

(57) ABSTRACT

A molded can package includes a circuit board, a MEMS die and a can. The MEMS die is connected to the circuit board by a conductive wire. The can is mounted to the circuit board so as to isolate the MEMS die to form a MEMS die unit. A compound mold packs the MEMS die unit to prevent the MEMS die from being interfered and physically damage by electro-magnetic radiation and light so as to simplify the manufacturing processes and increase the production and reduce the cost.

### FIELD OF THE INVENTION

The present invention relates to a molded can package, and more particularly, to a package for MEMS die wherein the can is used to prevent the MEMS die from being interfered and physically damage by electro-magnetic radiation and light so as to simplify the manufacturing processes and increase the production and reduce the cost.

### BACKGROUND OF THE INVENTION

The conventional molded can package for MEMS die is disclosed in the attachment 1 which is the Taiwan Patent No. I324890 and provides a cap wafer 11 and a micro electro-mechanical system wafer (MEMS wafer) 13 which is connected with the cap wafer 11. A film 15 is mounted to the top of the cap wafer 11. Multiple MEMS wafers 13 with the cap wafer 11 connected thereto are put on an adhesive strip 16 and cutting steps are applied to the MEMS wafers 13 and the cap wafer 11 to form the MEMS devices 17. The MEMS devices 17 are connected to a base board 18 and both of the MEMS devices 17 and the base board 18 are packed by encapsulating 20. When cutting the MEMS systems 17, a wiring area is maintained at the top of the MEMS wafers 13. However, the disclosed method requires two times of processes to proceed the package and wastes time and material (both of the MEMS wafers 13 and the cap wafers 11 are required). This method has higher cost and involves complicated processes which delay the schedule of production. Furthermore, in order to save the chips, when cutting the MEMS devices 17, only the margin area is used for wiring and the wires are easily separated from the MEMS devices 17 due to the high pressing force when packing. The yield rate is increased.

The present invention intends to provide a molded can package and directly mounting a can to the MEMS dies to prevent the MEMS die from being interfered and physically damage by electro-magnetic radiation and light so as to simplify the manufacturing processes and increase the production and reduce the cost.

### SUMMARY OF THE INVENTION

The present invention relates to a molded can package and comprises a circuit board to which a MEMS die is connected by a conductive wire. A can has a can supporting bar extending from each of two ends thereof. The can is a hollow can and cooperated with the circuit board and the MEMS die to form a MEMS die unit. A compound mold packs the MEMS die unit.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a cross sectional view of the MEMS die units packed by the molded can package of the present invention;

FIG. 2 is a cross sectional view to show that the MEMS die units are located in the compound mold of the present invention;

FIG. 3 is a cross sectional view to show that the MEMS die units are packed in the molded can package of the present invention;

FIG. 4 is a cross sectional view to show that the MEMS die units are packed and are cut into multiple MEMS die units, and

FIG. 5 is a second embodiment of the molded can package of the present invention.

### DETAILED DESCRIPTION OF THE PREFERRED EMBODIMENT

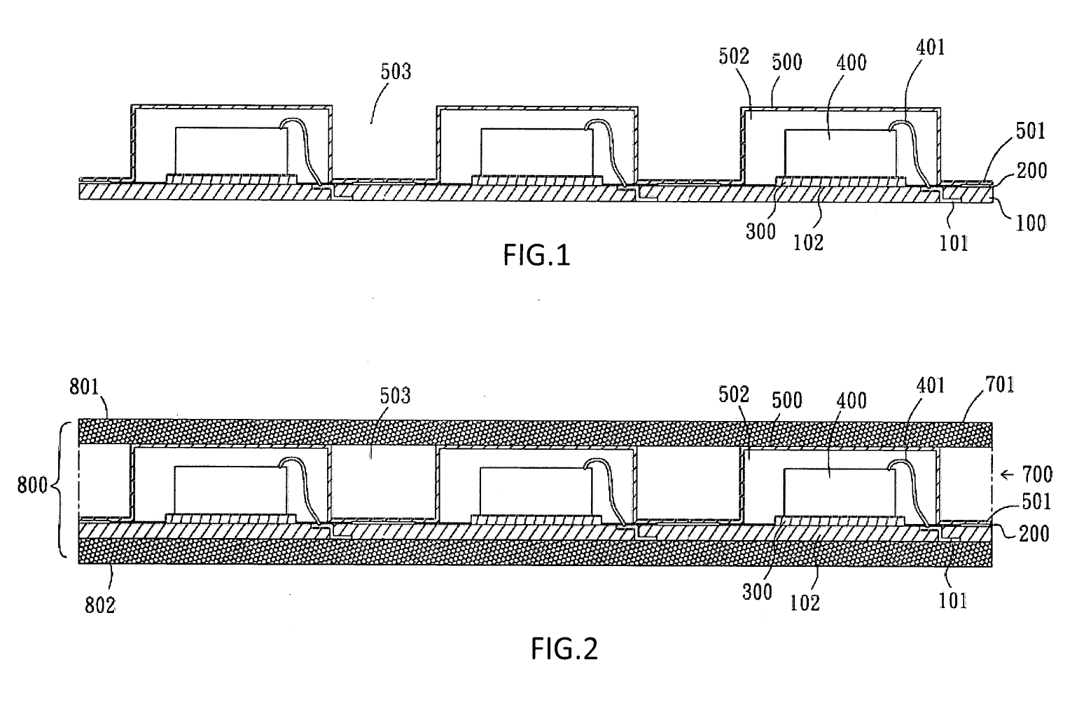

Referring to FIG. 1, the molded can package of the present invention comprises a circuit board 100 having a circuit board circuit 101 connected thereto and the top 102 of the circuit board 100 has can adhesive 200 spread thereto so as to adhere a can 500.

A MEMS die 400 is connected with the circuit board 100 by MEMS die adhesive 300.

A conductive wire 401 is welded between the circuit board circuit 101 of the circuit board 100 and the MEMS die 400 so that communication is built between the circuit board 100 and the MEMS die 400.

The can 500 is recessed can with an open end and a closed end, two can supporting bars 501 respectively extend from two ends of the open end. For mass production purpose, the cans 500 and the can supporting bars 501 are continuously connected to each other. In other words, the cans 500 and the can supporting bars 501 are alternatively connected to each other. The can 500 is in a shape of rectangular, circular, square and polygonal shape.

When packing the MEMS dies 400, because the MEMS dies 400 easily receive radiation to contaminate the chips, therefore, the MEMS dies 400 are prepared in a clean room. The circuit board 100 has a circuit board circuit 101 connected thereto and the top 102 of the circuit board 100 has can adhesive 200 and MEMS die adhesive 300 spread thereto. When spreading the can adhesive 200 and MEMS die adhesive 300, the circuit board circuit 101 is isolated from the two adhesives 200, 300.

When the can adhesive 200 and MEMS die adhesive 300 are spread, the MEMS dies 400 are adhered by the MEMS die adhesive 300. One end of the conductive wire 401 is welded to the side of the MEMS die 400 that is not connected with the MEMS die adhesive 300. The other end of the conductive wire 401 is welded to the circuit board circuit 101 of the circuit board 100.

When the MEMS dies 400 are secured and communicates with the circuit board circuit 101 of the circuit board 100, the can 500 are put on the circuit board 100 and accommodate the MEMS die 400, the conductive wire 401 and the circuit board circuit 101 in the can cavity 502 of the can 500. The can supporting bars 501 of the can 500 are adhered to the circuit board 100 by the MEMS die adhesive 300 to form the MEMS die unit 70.

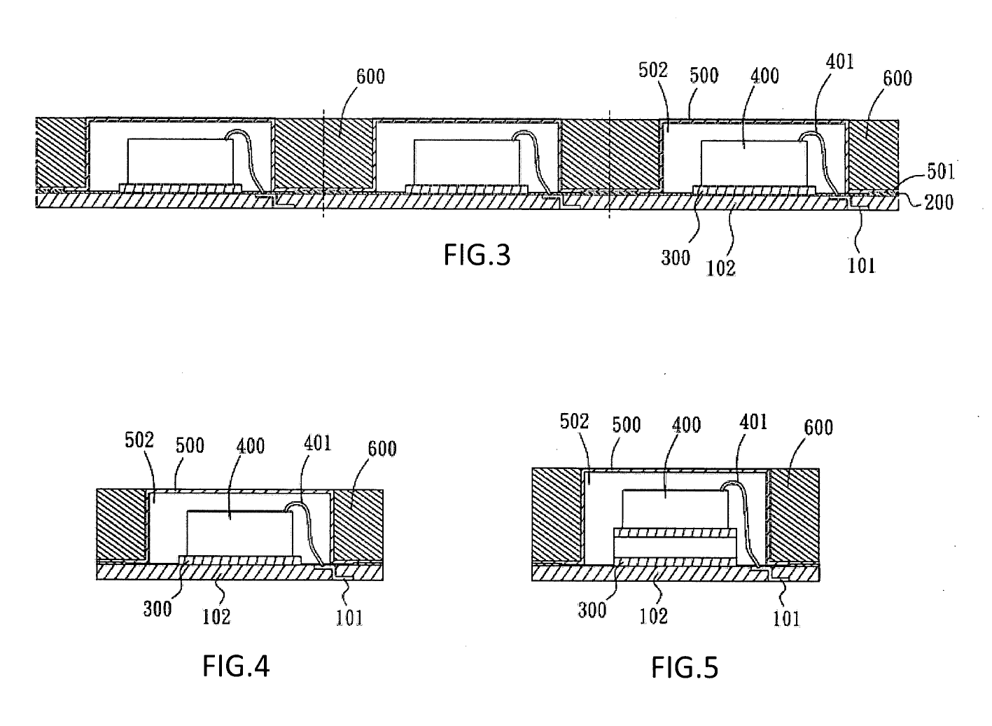

As shown in FIGS. 2 to 4, when the MEMS die units 70 are set, the MEMS die units 70 are put in the down mold 802 of the compound mold 800, and the upper mold 801 of the compound mold 800 is mounted on the tops 701 of the MEMS die units 70. By applying pressure, the cans 500 and the circuit board 100 are more secured. The epoxy compound 600 is then filled in the gaps 503 between the top of the can supporting bars 501 in the cans 500 to pack the MEMS die units 70. The multiple packed the MEMS die units 70 are then cut into several single pieces to obtain the multiple MEMS dies 400.

As shown in FIG. 5 which shows the second embodiment of the present invention, the difference from the previous embodiment is that the MEMS die adhesive 300 can adhere two or more than two MEMS dies 400 which are allowable to be overlapped in the can cavity 502 of the can 500 to increase the capacity of the single MEMS die 400.

The processes of the molded can package of the present invention are simplified than those of the conventional method, the material is also saved. The signals for the MEMS dies 400 are more stable than the conventional ones. The manufacturing cost and the material required are reduced, while the efficiency and the yield rate are increased.

While we have shown and described the embodiment in accordance with the present invention, it should be clear to those skilled in the art that further embodiments may be made without departing from the scope of the present invention.

What is claimed is:

1. A molded can package comprising:
a circuit board;
a MEMS die;
a conductive wire welded between the circuit board and the MEMS die;
a can having a can supporting bar extending from each of two ends thereof, the can being a hollow can and cooperated with the circuit board and the MEMS die to form a MEMS die unit, and
a compound mold packing the MEMS die unit.

2. The molded can package as claimed in claim 1, wherein the circuit board has a circuit board circuit connected thereto.

3. The molded can package as claimed in claim 1, wherein the MEMS die is connected to the circuit board by MEMS die adhesive.

4. The molded can package as claimed in claim 1, wherein the can is connected to the circuit board by can adhesive.

5. The molded can package as claimed in claim 1, wherein the compound mold comprises an upper mold and a down mold.

6. The molded can package as claimed in claim 1, wherein the can is in a shape of rectangular, circular, square and polygonal shape.
